(19) United States
(12) Patent Application Publication
(10) Pub. No.: US 2008/0315412 A1
(43) Pub. Date: Dec. 25, 2008

(54) Package Structure with Flat Bumps for Integrate Circuit or Discrete Device and Method of Manufacture the Same

(75) Inventors: Jerry Liang, Xinzhu County (TW); Jieren Xie, Jiangsu (CN); Xinchao Wang, Jiangsu (CN); Xiekang Yu, Jiangsu (CN); Yujuan Tao, Jiangsu (CN); Rongfu Wen, Jiangsu (CN); Fushou Li, Jiangsu (CN); Zhengwei Zhou, Jiangsu (CN); Da Wang, Jiangsu (CN); Haibo Ge, Jiangsu (CN); Qiang Zheng, Jiangsu (CN); Zhen Gong, Jiangsu (CN); Weijun Yang, Jiangsu (CN)

Correspondence Address: HESLIN ROTHENBERG FARLEY & MESITI PC, 5 COLUMBIA CIRCLE, ALBANY, NY, 12203, US

(73) Assignee: Jiangsu Changjiang Electronics Technology Co., Ltd, Jiangyin (CN)

(21) Appl. No.: 11/910,885

(22) PCT Filed: Apr. 6, 2006
(86) PCT No.: PCT/CN2006/000609

§ 371 Date: May 16, 2008

(30) Foreign Application Priority Data
Apr. 7, 2005 (CN) 200510038818.3
May 27, 2005 (CN) 200510040261.7
May 27, 2005 (CN) 200510040262.1
Jul. 2, 2005 (CN) 200510041043.5
Jul. 2, 2005 (CN) 200510041044.X
Jul. 5, 2005 (CN) 200510041069.X
Jul. 5, 2005 (CN) 200510041070.2
Jul. 18, 2005 (CN) 200510041274.6
Jul. 18, 2005 (CN) 200510041275.0

(51) Int. Cl. H01L 23/52; H01L 21/00

(52) U.S. Cl. 257/737; 438/121; 257/E23.141; 257/E21.001

(57) ABSTRACT

The invention discloses a novel package structure of integrate circuit or discrete device and packaging method, and includes the lead pins adjacent to the island; another metal layer formed at the bottom of the island; another metal layer formed at the bottom of lead pins; chip mounted on the island; wires bonded between the chip and the lead pins; the molded body encapsulating the top surface and side surface of the island and the lead pins, small protrusions of the island and the lead pins below the molded body; in the individual package, the number of the island can be one or more, lead pins can be arrayed at one side of the island, also can be arrayed at two sides or three sides of the island, one or two rows of lead pins can be located around the island. The invention provides strong welding, good quality, low cost, smooth production, wide applicability, flexible arrangement of the chips.

### CROSS-REFERENCE TO RELATED APPLICATIONS

This application is a §371 filing of PCT application CN2006/000609 which claims priority from Chinese application 200510038818.3 filed on Apr. 7, 2005, Chinese application 200510040262.1 filed on May 27, 2005, Chinese application 200510040261.7 filed on May 27, 2005, Chinese application 200510041044.X filed on Jul. 2, 2005, Chinese application 200510041043.5 filed on Jul. 2, 2005, Chinese application 200510041069.X filed on Jul. 5, 2005, Chinese application 200510041070.2 filed on Jul. 5, 2005, Chinese application 200510041275.0 filed on Jul. 18, 2005 and Chinese application 200510041274.6 filed on Jul. 18, 2005. The disclosures of these applications are hereby included by reference herein in their entirety.

### FIELD OF THE INVENTION

The present invention relates to a new package structure with flat bumps for integrated circuits and discrete devices and a method of manufacturing the package structure, and belongs to the technical field of packaging of electronic devices.

### BACKGROUND OF THE INVENTION

In the traditional leadless flat bond packaging process and structure for integrated circuits or discrete devices, the package is an integral unit cut from an array assembly. The substrate is in the form of a lead frame. They mainly have the following drawbacks:

1. Specific glue film: the specific glue film is used to prevent the packaging material from impregnating to the rear part of the lead frame and thereby increasing the risk to insulation of the outer pins during encapsulation under high pressure. However, the specific glue film still can't completely prevent overflow of the thermoplastic packaging material. If impregnation of the thermoplastic packaging material still exists, the galvanized coating on the pins may be damaged during post-treatment, and therefore degrades solderability. As a result, the material cost, post-treatment cost, and quality will be affected to a certain degree.

2. Palladium plating on both sides of the substrate: in order to ensure the wiring process and the manufacturing of outer pins can be completed in this process, expensive palladium material is coated on both sides of the lead frame. Therefore, the electroplating cost is high, and the wiring parameters have to be set specially for the material. As a result, the smooth operation of the production line will be affected due to inconsistency of parameters.

3. Contamination: since the lead frame employs a sort of special chemical glue film, the solvent in the tape may be gasified under high temperature in different high temperature processes, and will contaminate or cover the pressing area of the chip and the wiring area of the pins, and thereby often causes unstable wiring.

4. Application flexibility of chip and outer pins: limited by the traditional lead frame, the chips and the outer pins have to be arranged in a fixed way. Therefore, the application is not flexible.

5. Solderability of the outer pins: limited by the traditional lead frame, the outer output pins are flush to the bottom of the molded body, and therefore are difficult to solder to the printed circuit board. As a result, the soldering strength is low.

6. Lead frame: since the lead frame is manufactured through a penetrative etching process, the lead frame structure is mild. Therefore, the substrate can't be made of high-purity copper material.

7. Metal wire ball bonding: since a penetrative etching process is used, the back of the substrate has to be coated with glue film to prevent material overflow. Since the glue film is soft, the soldering points may swash during wire soldering, which will cause loose contact of the soldering points and severely degrade reliability and production stability of the solder wires.

8. Reliability

A. Though the chemical glue film is coated, certain material overflow will still exist in the high temperature encapsulation process.

B. Since heavy rework is required in case of material overflow, the encapsulation pressure can't be high. As a result, the thermoplastic encapsulation material will be loose, the water absorption rate will increase, and the density will decrease, which will severely increase the production cost and decrease the qualified rate;

C. The output pin part of the product manufactured through leadless flat bond packaging is flush to the bottom of the molded body or even recessed, bad contact may occur due to the poor coplanarity of the pin surfaces in the surface mounting process. In addition, since the external pins are recessed on the surface of the thermoplastic body, air may be trapped in the recess in the surface mounting process, and therefore causes breaking of the contacts due to gas dilatation under high temperature.

D. Since the output pins are flush to the bottom of the thermoplastic body or even recessed, the Sn paste on the pins may bond together and cause short circuit under pressing in the surface mounting process.

E. The inner pins are usually coated with silver coating, however, the silver coating doesn't bond well to the packaging material. As a result, delamination may occur between the packaging material and the silver coating.

F. The outer pins that provide electrical output are usually made of Sn—Pd alloy or pure Sn, which is easily oxidized and therefore affect solderability. Furthermore, the shelf life of the product will be short.

G. Since the outer pins that provide electrical output are usually made of Sn—Pd alloy or pure Sn and the Sn material has a low melting point, the Sn material may be oxidized or even melted under the heat generated from friction with the cutting tool in the cutting process. Therefore, the solderability and the stability of electrical output of the outer pins will be severely degraded.

9. Heat dissipation capability and conductivity: since the lead frame manufactured through leadless flat bond packaging process employs fully etched copper alloy, the conductivity/heat dissipation capability is only about 65%. If pure copper is used, the conductivity/heat dissipation capability can be at least 90%. However, since pure copper is too soft, high-purity copper can't be used in the fully etched lead frame that is very low in structure rigidity to improve heat dispersion capability and electrical conductivity.

### BRIEF SUMMARY OF THE INVENTION

### Technical Problem

To overcome above drawbacks, the present invention provides a package structure with flat bumps for integrated circuits or discrete devices and a method of manufacturing the package structure, which are featured with high solderability, high product reliability, high quality, low cost, smooth production, wide applicability, flexible arrangement of chips, flexible arrangement of pins/pin positions, free of loose soldering points in inner pins or overflow of the packaging material, etc.

### Technical Solution

The package structure with flat bumps for integrated circuits or discrete devices provided in the present invention comprises a chip support base, a lead support base, a chip, metal wires, and a molded body, wherein the lead support base is arranged adjacent to the chip support base, the chip support base is based on an island, which is coated with another metal layer on the back; the lead pin part mainly comprises the lead pins, which are coated with another metal layer on the back; the chip is bonded on the chip support base and is connected to the lead support base through metal wires, the molded body covers the upper part and the sides of the chip support base and the lead support base, and the lower parts of the chip support base and lead support base protrude from the molded body; in such a package body for integrated circuits or discrete devices, one or more chip support base islands can be arranged, and the lead pins can be arranged on one side, two sides, or three sides of the island, or around the island, to form a structure with one or more rows of lead pins.

Said island is coated with an active substance on the back, with a metal layer coated on the active substance. The lead pin part mainly comprises on the pins, which are coated with an active substance on the back, with a metal layer coated on the active substance. Or, the lead pins are coated with a metal layer on the front. Or, the island is coated with an active substance on the back, with a metal layer coated on the active substance; the lead pin part mainly comprises the lead pins, which are coated with an active substance on the front and back, with a metal layer coated on the active substance. Or, the island is coated with a metal layer on the front; the lead pin part mainly comprises the lead pins, which are coated with a metal layer on the front. Or, the island is coated with an active substance on front and back, with a metal layer coated on the active substance; the lead pin part mainly comprises the lead pins, which are coated with an active substance on the front and back, with a metal layer coated on the active substance.

A bonding substance is arranged between the island and the chip. The metal layer is select form the group of Au, Ag, Cu, Sn, Ni, or Ni—Pd. The metal wires are gold wires, silver wires, copper wires, or aluminum wires. Said active substance is Ni, Pd, or Ni—Pd.

The procedures of the method of manufacturing the package structure with flat bumps for integrated circuits or discrete devices are:

1) Take a packaging substrate with flat bumps for integrated circuits or discrete devices, wherein, the island and pins on said metal substrate are coated with a metal layer on the back;

2) Implant a chip 3 on the front side of the chip support base 1 on the packaging substrate with flat bumps, to fabricate a semi-finished product of an array or assembly of integrated circuits or discrete devices;

3) Carry out wiring with metal wires 4 for the semi-finished product after chip implantation, i.e., connect the chip 3 to the corresponding pins on the lead support base 2 with the metal wires;

4) Encapsulate the front side of the semi-finished product after metal wiring in a molded body 5, and then cure the molded body;

5) Each the metal layer in the areas that is not covered by the other metal layer, that is the areas between the pins and the areas between the pins and the island, on the back of the packaging substrate with flat bumps, so as to separate the pins from each other and separate the pins from the island, to form a structure with bumps protruding from the molded body;

6) Coat a glue film on the front of the molded body 5;

7) Cut the semi-finished product coated with glue film, to separate the integrated circuits or discrete devices that were connected in an array or assembly;

8) Print the semi-finished product on the front after encapsulation in the molded body 5 and the molded body 5 is cured.

A bonding substance can be coated on the front of the chip support base 1 before the chip 3 is implanted. Before the chip 3 is implanted on the front of the chip support base 1 on the packaging substrate with flat bumps, a metal layer can be coated on the chip support base 1; or, an active substance can be coated on the chip support base 1 and then another metal layer can be coated on the active substance.

### Beneficial Effects

1. Metal substrate: since the metal substrate is fabricated through a semi-etching process, the metal substrate structure is relatively rigid. Therefore, the substrate can be made of high-purity copper.

2. Chemical glue film: since the substrate is fabricated through a semi-etching process, no material overflow will occur during the encapsulation process. Furthermore, it does't need to apply glue film to prevent overflow. Therefore, the product quality can be improved, and the production cost can be reduced.

3. Contamination: since material overflow can be prevented in the encapsulation process without any chemical glue film, no contamination related to the glue film will occur. Therefore, the production will be smooth, the qualified rate will be higher, and the cost will be low.

4. Metal wire soldering: since a metal substrate fabricated through a semi-etching process is used, the inner pins and the metal substrate are in an integral structure, and the positions of the inner pins will be stable in the wiring process, and thereby no loose pin soldering point will occur; as a result, the production will be smoother.

5. Solderability of outer pins: in the package structure with flat bumps, the outer output pins protrude from the bottom of the molded body. Therefore, the outer pins in the form of bumps can be soldered more easily and firmly to the printed circuit board. Moreover, the twice etching process ensures absolute coplanarity between the outer pins and makes the manufacturer worry free about instability of surface bonding. Therefore, compared to the traditional leadless flat bond packaging structure, this product is superior in quality.

6. Reliability

A. No material overflow will occur during encapsulation with the molded body;

B. Since a semi-etching process is used, no material overflow will occur even if higher pressure is used in the encapsulation process. Therefore, the product reliability is ensured, and the production will be smoother, and the cost will be reduced.

C. Since the output pins on the bottom of the molded body protrude from the molded body, the residual Sn paste will attach around the pins. Therefore, short circuit in the Sn paste can be avoided, and the bonding strength of the outer pins in the form of bumps will be increased.

D. The inner pins in the wiring area are coated with Au, Ni, or Ni—Pd instead of Ag. Due to the fact that the bonding strength between the encapsulation material and Au, Ni, or Ni—Pd is much higher than that between the capsulation and Ag, no delamination will occur.

E. The outer pins that provide electrical output are coated with Au, Ni, or Ni—Pd. Since the coating material is an inert material, it will not be oxidized in the ambient gas or due to the temperature factor; therefore, the shield life of the product will be very long;

F. The outer pins that provide electrical output are coated with Au, Ni, or Ni—Pd; since the coating material is an inert metal material with a high melting point, the coating on the outer pins will not be oxidized under the heat resulted from friction in the cutting process. Therefore, the solderability and the stability of electrical transmission of the output pins are ensured, and the product quality is improved.

7. Heat dissipation capability and conductivity: since the package metal substrate with flat bumps is fabricated through a semi-etching process, the structural strength of the base board is significantly higher than any lead frame fabricated through a penetrative etching process. Therefore, the metal base board can be made of high-purity copper material, so as to improve heat dissipation and electrical transmission performance.

### BRIEF DESCRIPTION OF THE DRAWINGS

These, and other objects, features and advantages of this invention will become apparent from the following detailed description of the various aspects of the invention taken in conjunction with the accompanying drawings, in which:

FIGS. 1-7 are schematic flow diagrams of the procedures in the present invention. Wherein, FIG. 7 is a schematic diagram of a structure in which the island and pins are coated with an active substance on the front and back, with another metal layer coated on the active substance.

FIG. 8 is a schematic diagram of a structure in which the island and pins are coated with another metal layer on the back.

FIG. 9 is a schematic diagram of a structure in which the pins are arranged around an island; wherein, FIG. 9b is a sectional view of the structure shown in FIG. 9a.

FIG. 10 is a schematic diagram of a structure in which the pins are arranged around a plurality of islands; wherein, FIG. 10b is a sectional view of the structure shown in FIG. 10a.

FIG. 11 is a schematic diagram of a structure in which multiple rows of pins are arranged around an island; wherein, FIG. 11b is a sectional view of the structure shown in FIG. 11a.

FIG. 12 is a schematic diagram of a structure in which two rows of pins are arranged on both sides of an island; wherein, FIG. 12b is a sectional view of the structure shown in FIG. 12a.

FIG. 13 is a schematic diagram of a structure in which multiple rows of pins are arranged on both sides of an island; wherein, FIG. 13b is a sectional view of the structure shown in FIG. 13a.

FIG. 14 is a schematic diagram of a structure in which a row of pins are arranged around a plurality of islands; wherein, FIG. 14b is a sectional view of the structure shown in FIG. 14a.

Brief Instruction of the reference number: 1—Base island; 2—Lead pin; 3—Chip; 4—Metal wire; 5—Molded body; 6—Active substance; 7—Metal layer.

### DETAILED DESCRIPTION OF THE PREFERRED EMBODIMENTS

The package structure with flat bumps for integrated circuits or discrete devices provided in the present invention comprises a base island 1, lead pins 2, a chip 3, metal wires 4, and a molded body 5, wherein the pins 2 are arranged adjacent to the island 1; the island is coated with another metal layer 7 on the back; the pins are coated with another metal layer on the back; the chip 3 is bonded on the island 1, and is connected to the pins through the metal wires 4; the molded body 5 covers the upper part and side parts of the island 1 and the pins 2; the upper parts of the island 1 and the pins 2 protrude from the molded body 5; in such an package structure for integrated circuits or discrete devices, one or more islands can be arranged, and the pins can be arranged on one side, two sides, or three sides of the island, or around the island, to form a structure with one or more rows of lead pins.

The following options are available for the structure:

Said island is coated with an active substance on the back, with another metal layer coated on the active substance. The pins are coated with an active substance on the back, with another metal layer coated on the active substance. Said pins are coated with another metal layer on the front.

Said island is coated with an active substance on the back, with another metal layer coated on the active substance. The pins are coated with an active substance on the front and back, with another metal layer coated on the active substance.

Said island is coated with another metal layer on the front. The pins are coated with another metal layer on the front.

Said island is coated with an active substance on the front and back, with another metal layer coated on the active substance. The pins are coated with an active substance on the front and back, with another metal layer coated on the active substance.

A bonding substance 8 is provided between the island 1 and the chip 3.

Said another metal layer 7 is select form the group of Au, Ag, Cu, Sn, Ni, or Ni—Pd. Said metal wires 4 are gold wires, silver wires, copper wires, or aluminum wires. Said active substance 6 is Ni, Pd, or Ni—Pd.

The packaging procedures in the present invention are as follows:

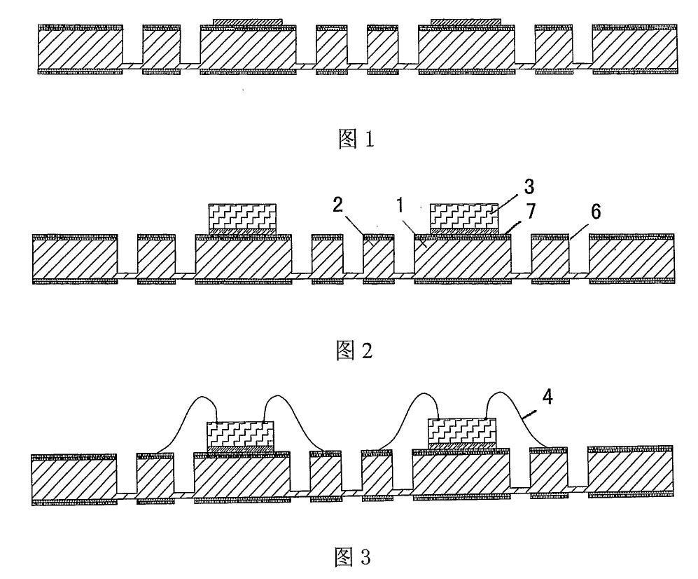

1) Taking a lead frame with flat bumps for integrated circuits or discrete devices and coating silver glue on the lead frame, as shown in FIG. 1: coat silver Adhesive (conductive adhesive/non-conductive adhesive) on the metal layer 7 on the island. If a shared crystal is to be used, it does not need to cover the silver glue.

2) Bonding operation, as shown in FIG. 2: implant a chip 3 into the metal layer 7 on the island 1 on the front of the lead frame with flat bumps, to fabricate a semi-finished product of an array or assembly of integrated circuits or discrete devices; or, implant the chip 3 in the chip area coated with silver glue, and then cure the silver glue in accordance with the characteristics of the silver glue, to fabricate a semi-finished product of an array or assembly of integrated circuits or discrete devices.

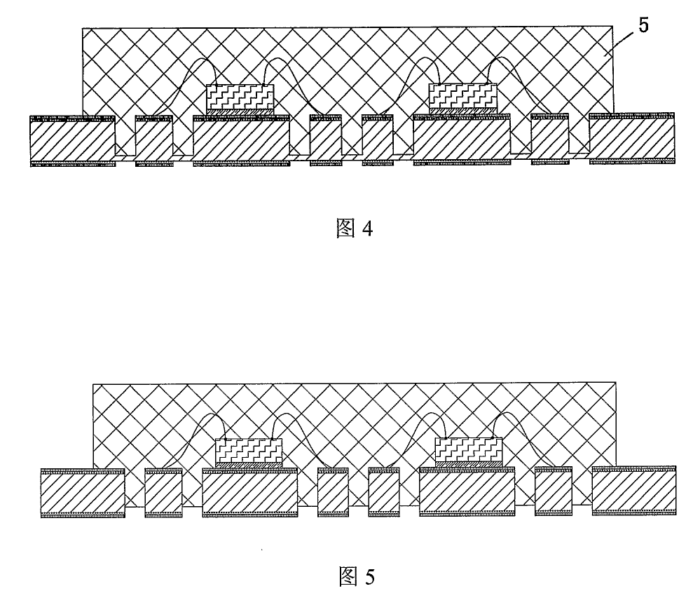

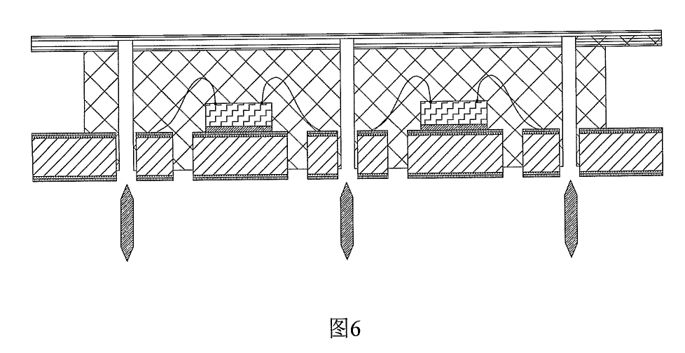

3) Metal wire ball bonding, as shown in FIG. 3: carry out metal wiring with the metal wires 4 for the semi-finished product after chip implantation, i.e., connect the chip 3 to the pin corresponding to pin 2 and the metal layer 7 on the island 1 with metal wires 4. The metal wires can be gold wires, silver wires, copper wires, or aluminum wires.

4) Encapsulation, as shown in FIG. 4: encapsulate the front part of the semi-finished product after wiring into a molded body 5, and then cure the molded body 5 in accordance with the characteristic of the packaging material, so as to ensure safety of the metal wires, chip, and inner pins.

5) Printing: print on the front of the semi-finished product after encapsulation and curing, to identify the functions and characteristics of the chip.

6) Coating of a film on the bottom of the island 1 and pins 2, and exposure of the area to be etched subsequently.

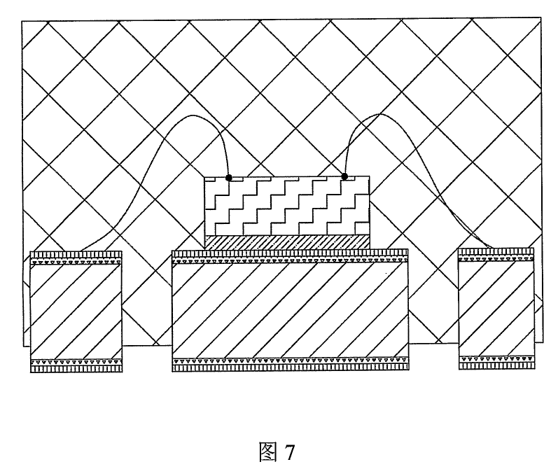

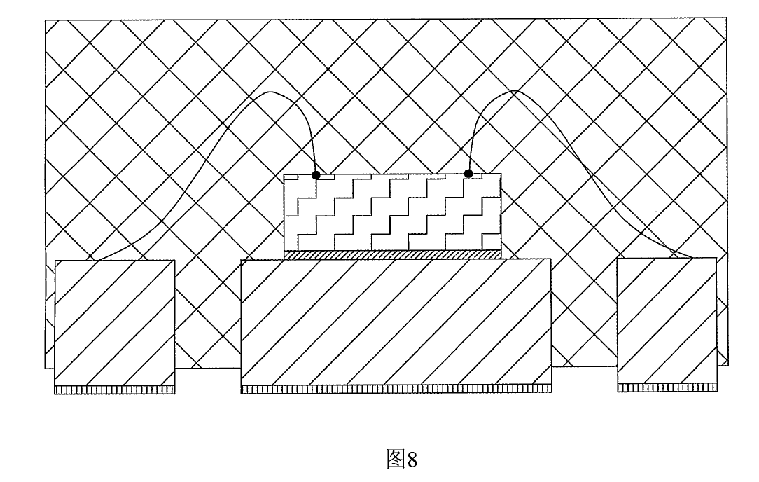

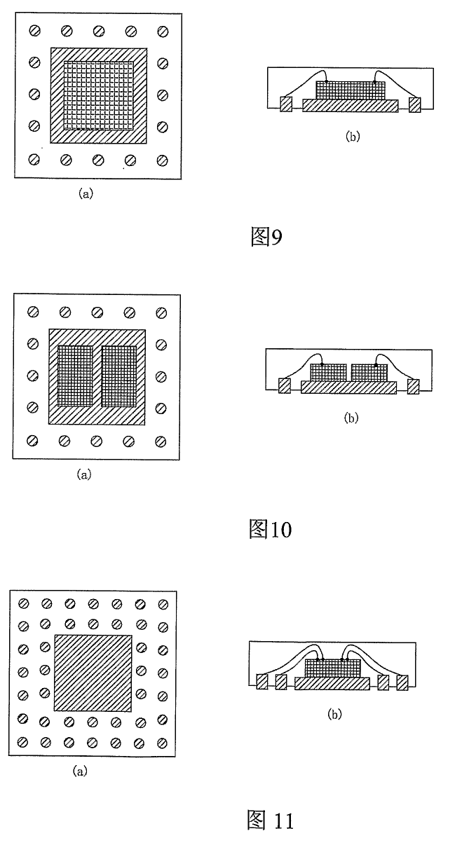

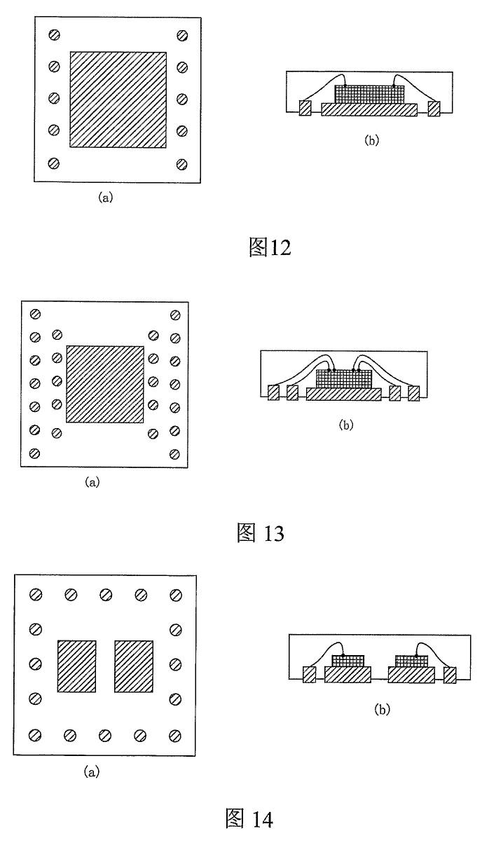

7) Etching on the back of the substrate, as shown in FIG. 7: after above procedure, etch the metal in the area that is not covered by the film (i.e., the semi-etching area) on the bottom of the lead frame with flat bumps, so as to separate the island 1 from pins on the bottom, and make the back of the pins protrude from the molded body 8.

8) Remove of the film on the bottom of the island 1 and the pins 2.

9) Coating of glue film on the front of the molded body 5, to prepare for the subsequent glue cutting work.

10) Molded body cutting, as shown in FIG. 12: cut the semi-finished product coated with the glue film, so as to separate the chips that were originally connected in an array or assembly from each other.

1. A package structure with flat bumps for integrated circuits or discrete devices, comprising a base island, lead pins, a chip, metal wires, and a molded body, wherein the pins are arranged adjacent to the island; the island is coated with another metal layer on the back; the pins are coated with another metal layer on the back; the chip is bonded on the island, and is connected to the pins through the metal wires; the molded body covers the upper part and side parts of the island and the pins; the upper parts of the island and the pins protrude from the molded body; in such an package structure for integrated circuits or discrete devices, one or more islands can be arranged, and the pins can be arranged on one side, two sides, or three sides of the island, or around the island, to form a structure with one or more rows of lead pins.

2. The package structure with flat bumps for integrated circuits or discrete devices according to claim 1, wherein said island is coated with an active substance on the back, with another metal layer coated in the active substance; said pins are coated with an active substance on the back, with a metal layer coated on the active substance.

3. The package structure with flat bumps for integrated circuits or discrete devices according to claim 1, wherein said pins are coated with a metal layer on the front.

4. The package structure with flat bumps for integrated circuits or discrete devices according to claim 1, wherein said island is coated with an active substance on the back, with another metal layer coated in the active substance; said pins are coated with an active substance on the front and back, with a metal layer coated on the active substance.

5. The package structure with flat bumps for integrated circuits or discrete devices according to claim 1, wherein said island is coated with a metal layer on the front; said pins are coated with a metal layer on the front.

6. The package structure with flat bumps for integrated circuits or discrete devices according to claim 1, wherein said island is coated with an active substance on the front and back, with another metal layer coated on the active substance; said pins are coated with an active substance on the front and back, with an metal layer coated on the active substance.

7. The package structure with flat bumps for integrated circuits or discrete devices according to any of claim 2, wherein the island can be partially or entirely covered by the metal layer.

8. The package structure with flat bumps for integrated circuits or discrete devices according to claim 1, wherein a bonding substance is arranged between said island and said chip.

9. The package structure with flat bumps for integrated circuits or discrete devices according to claim 1, wherein said another metal layer is select form the group of Au, Ag, Cu, Sn, Ni, or Ni—Pd.

10. The package structure with flat bumps for integrated circuits or electronic device according to claim 1, wherein said metal wires are gold wires, silver wires, copper wires, or aluminum wires.

11. The package structure with flat bumps for integrated circuits or electronic device according to claim 2, wherein said active substance is Ni, Pd, or Ni—Pd.

12. A method for manufacturing the package structure with flat bumps for integrated circuits or discrete devices according to claim 1, wherein said method comprises the following packaging procedures:
1) Taking a packaging substrate with flat bumps for integrated circuits or discrete devices, wherein the island and pins on said metal substrate being coated with a metal layer on the back;
2) Implanting a chip on the front side of the island on the packaging substrate with flat bumps, to fabricate a semi-finished product of an array or assembly of integrated circuits or discrete devices;
3) Carrying out wiring with metal wires for the semi-finished product after chip implantation, that is, connect the chip to the corresponding pins with the metal wires;
4) Encapsulating the front side of the semi-finished product after metal wiring in a molded body, and then cure the molded body;
5) Etching the metal layer in the areas that is not covered by the other metal layer, that is the areas between the pins, and the areas between the pins and the island, on the back of the packaging substrate with flat bumps, so as to separate the pins from each other and separate the pins from the island, to form a structure with bumps protruding from the molded body;
6) Coating a glue film on the front of the molded body;
7) Cutting the semi-finished product coated with glue film, to separate the integrated circuits or discrete devices that were connected in an array or assembly.

13. The method of manufacturing the package structure with flat bumps for integrated circuits or discrete devices according to claim 12, wherein a bonding substance is coated on the front of the island before the chip is implanted.

14. The package structure with flat bumps for integrated circuits or discrete devices according to claim 12, wherein printing is carried out on the front of semi-finished product after encapsulation in the molded body and curing of the molded body.

15. The package structure with flat bumps for integrated circuits or discrete devices according to claim 12, wherein before the chip is implanted on the front of the island on the packaging substrate with flat bumps, a metal layer can be coated on the front of the island and the lead support base; or, an active substance can be coated on the front of the island and the lead support base and then a metal layer can be coated on the active substance.
